(19) United States
(12) Patent Application Publication
(10) Pub. No.: US 2025/0294719 A1
(43) Pub. Date: Sep. 18, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Taegon LEE, Suwon-si (KR); Kangin LEE, Suwon-si (KR); Jieun HA, Suwon-si (KR); Minkyu KANG, Suwon-si (KR)

(73) Assignee: Samsung Electronics Co., Ltd., Suwon-si (KR)

(21) Appl. No.: 18/938,616

(22) Filed: Nov. 6, 2024

(30) Foreign Application Priority Data
Mar. 18, 2024 (KR) 10-2024-0037165

(51) Int. Cl. H10B 12/00; H01L 23/522; H01L 23/532; H10B 43/27; H10B 43/35; H10B 43/40

(52) U.S. Cl. CPC H10B 12/315; H01L 23/5226; H01L 23/53295; H10B 12/0335; H10B 12/50; H10B 43/27; H10B 43/35; H10B 43/40

(57) ABSTRACT

A semiconductor device including a first semiconductor structure including a lower interconnection structure electrically connected to circuit devices, and a capacitor structure spaced apart from the lower interconnection structure; and a second semiconductor structure including a memory cell array. The capacitor structure includes a first electrode structure including first electrodes spaced apart from each other in a first direction parallel to an upper surface of the substrate and extending in a vertical direction and a second direction intersecting the first direction; and a second electrode structure including second electrodes arranged alternately with the first electrodes and extending in the second direction. The first and second electrodes each include a first wall pattern having a first side surface, and a second wall pattern having a second side surface extending from the first side surface. A side surface profile changes nonlinearly at a boundary between the first and second side surfaces.

### CROSS-REFERENCE TO RELATED APPLICATION(S)

This application claims benefit of priority to Korean Patent Application No. 10-2024-0037165 filed on Mar. 18, 2024 in the Korean Intellectual Property Office, the disclosure of which is incorporated herein by reference in its entirety.

### BACKGROUND

Some example embodiments of the present disclosure relate to semiconductor devices and data storage systems including the same.

A semiconductor device able to store high-capacity data in a data storage system requiring data storage has been necessary. Accordingly, a method for increasing data storage capacity of a semiconductor device has been researched. Also, a semiconductor device having increased integration density has been necessary. For example, as a method for increasing integration density of a semiconductor device, a semiconductor device including memory cells and a peripheral circuit region disposed vertically has been suggested.

### SUMMARY

Some example embodiments of the present disclosure provide semiconductor devices including a capacitor structure having improved integration density and reliability, and data storage systems including the same.

Some example embodiments of the present disclosure provide a semiconductor device that includes a first semiconductor structure including a substrate, circuit devices on the substrate, a lower interconnection structure electrically connected to the circuit devices, and a capacitor structure spaced apart from the lower interconnection structure; and a second semiconductor structure including a plate layer on the first semiconductor structure, the second semiconductor structure including gate electrodes spaced apart from each other and stacked in order on the plate layer in a vertical direction perpendicular to an upper surface of the plate layer, and channel structures penetrating the gate electrodes and extending in the vertical direction. The capacitor structure includes a first electrode structure including first electrodes spaced apart from each other in a first direction parallel to an upper surface of the substrate, the first electrodes extending in the vertical direction and extending in a second direction intersecting the first direction; and a second electrode structure including second electrodes arranged alternately with the first electrodes along the first direction, the second electrodes extending in the second direction. The first electrodes and the second electrodes each include a first wall pattern having a first side surface and a second wall pattern having a second side surface, the second side surface extending from the first side surface. A side surface profile of the first and second electrodes changes nonlinearly at a boundary between the first side surface and the second side surface.

Some example embodiments of the present disclosure further provide a semiconductor device that includes a first lower electrode structure on a substrate, the first electrode structure including first lower electrodes and a first lower connection portion, the first lower electrodes being spaced apart from each other in a first direction parallel to an upper surface of the substrate and extending in a second direction intersecting the first direction, and the first lower connection portion connecting the first lower electrodes to each other and extending in the first direction; a second lower electrode structure including second lower electrodes and a second lower connection portion, the second lower electrodes being arranged alternately with the first lower electrodes along the first direction, and the second lower connection portion connecting the second lower electrodes to each other and extending in the first direction; a first insulating layer between the first lower electrode structure and the second lower electrode structure; a first intermediate electrode structure including first intermediate electrodes and a first intermediate connection portion, the first intermediate electrodes being on the first lower electrodes, and the first intermediate connection portion connecting the first intermediate electrodes to each other and extending in the first direction, the first intermediate connection portion overlapping the second lower connection portion in the vertical direction; a second intermediate electrode structure including second intermediate electrodes and a second intermediate connection portion, the second intermediate electrodes being on the second lower electrodes, and the second intermediate connection portion connecting the second intermediate electrodes to each other and extending in the first direction, and the second intermediate connection portion overlapping the first lower connection portion in the vertical direction; and a second insulating layer between the first intermediate electrode structure and the second intermediate electrode structure. The first intermediate electrodes and the second intermediate electrodes each include a first wall pattern having a first side surface and a second wall pattern having a second side surface, the second side surface extending from the first side surface. A side surface profile of the first and second intermediate electrodes changes nonlinearly at a boundary between the first side surface and the second side surface.

Some example embodiments of the present disclosure still further provide a data storage system that includes a semiconductor storage device including circuit devices, memory cells, capacitor structures, and input/output pads on a substrate; and a controller that controls the semiconductor storage device, the controller being electrically connected to the semiconductor storage device through the input/output pad. The capacitor structure includes a first electrode structure including first electrodes and a first connection portion, the first electrodes being spaced apart from each other in a first direction parallel to an upper surface of the substrate and extending in a second direction intersecting the first direction, and the first connection portion connecting the first electrodes to each other and extending in the first direction; a second electrode structure including second electrodes and a second connection portion, the second electrodes being arranged alternately with the first electrodes along the first direction and extending in the second direction, and the second connection portion connecting the second electrodes to each other and extending in the first direction; and an insulating layer between the first electrode structure and the second electrode structure. The first electrodes and the second electrodes each include a first wall pattern having a first side surface and a second wall pattern having a second side surface, the second side surface extending from the first side surface. A lower surface of the first connection portion and a lower surface of the second connection portion are at a level higher than a level of a lower surface of the first wall pattern.

### BRIEF DESCRIPTION OF DRAWINGS

The above and other aspects, features, and advantages of the present disclosure will be more clearly understood from the following detailed description, taken in combination with the accompanying drawings, in which:

FIG. 1A is a block diagram illustrating a semiconductor device according to some example embodiments of the present disclosure;

FIG. 1B is a circuit diagram describing a charge pump circuit included in a voltage generator of a semiconductor device according to some example embodiments of the present disclosure;

FIG. 1C is a perspective diagram illustrating a semiconductor device according to some example embodiments of the present disclosure;

FIG. 2A is a perspective diagram describing a capacitor structure of a semiconductor device according to some example embodiments of the present disclosure;

FIG. 2B is a plan diagram describing first and second lower electrode structures of a capacitor structure in FIG. 2A according to some example embodiments of the present disclosure;

FIG. 2C is a plan diagram describing first and second electrode structures of a capacitor structure in FIG. 2A according to some example embodiments of the present disclosure;

FIG. 3 is a cross-sectional diagram describing a capacitor structure in FIGS. 2B and 2C taken along line I-I′;

FIG. 4A is a perspective diagram describing a lower interconnection structure of a semiconductor device according to some example embodiments of the present disclosure;

FIG. 4B is a plan diagram describing a lower interconnection structure in FIG. 4A according to some example embodiments of the present disclosure;

FIG. 5 is a cross-sectional diagram describing a lower interconnection structure in FIG. 4B taken along line II-II′ according to some example embodiments of the present disclosure;

FIG. 6A is a perspective diagram describing a capacitor structure of a semiconductor device according to some example embodiments of the present disclosure;

FIG. 6B is a plan diagram describing first and second upper electrode structures of a capacitor structure in FIG. 6A according to some example embodiments of the present disclosure;

FIG. 7 is a cross-sectional diagram describing a capacitor structure in FIG. 6B taken along line III-III′ according to some example embodiments of the present disclosure;

FIG. 8A is a perspective diagram describing a lower interconnection structure of a semiconductor device according to some example embodiments of the present disclosure;

FIG. 8B is a plan diagram describing a lower interconnection structure in FIG. 8A according to some example embodiments of the present disclosure;

FIG. 9 is a cross-sectional diagram describing a lower interconnection structure in FIG. 8B taken along line IV-IV′ according to some example embodiments of the present disclosure;

FIG. 10 is a cross-sectional diagram illustrating a semiconductor device according to some example embodiments of the present disclosure;

FIGS. 11A, 11B, 11C, 11D, 11E, 11F and 11G are diagrams describing a method of manufacturing a semiconductor device according to some example embodiments of the present disclosure; and

FIG. 12 is a diagram describing a data storage system including a semiconductor device according to some example embodiments.

### DETAILED DESCRIPTION

Hereinafter, embodiments of the present disclosure will be described as follows with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

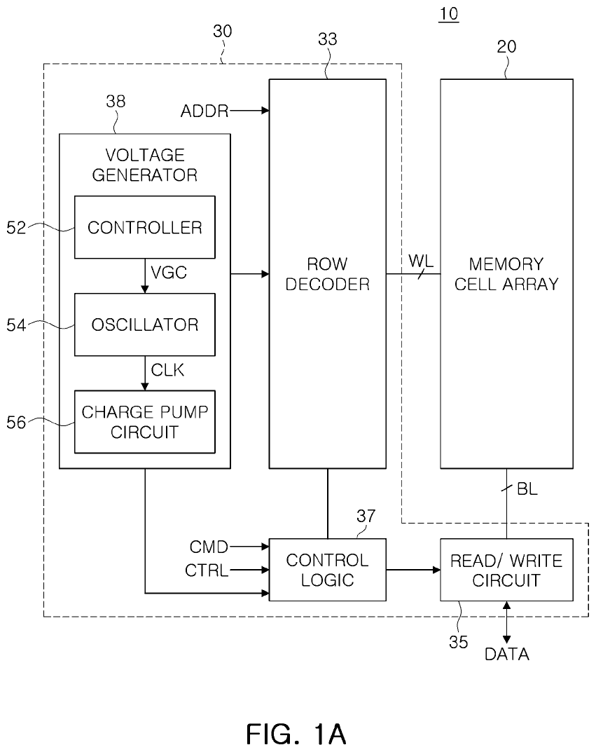

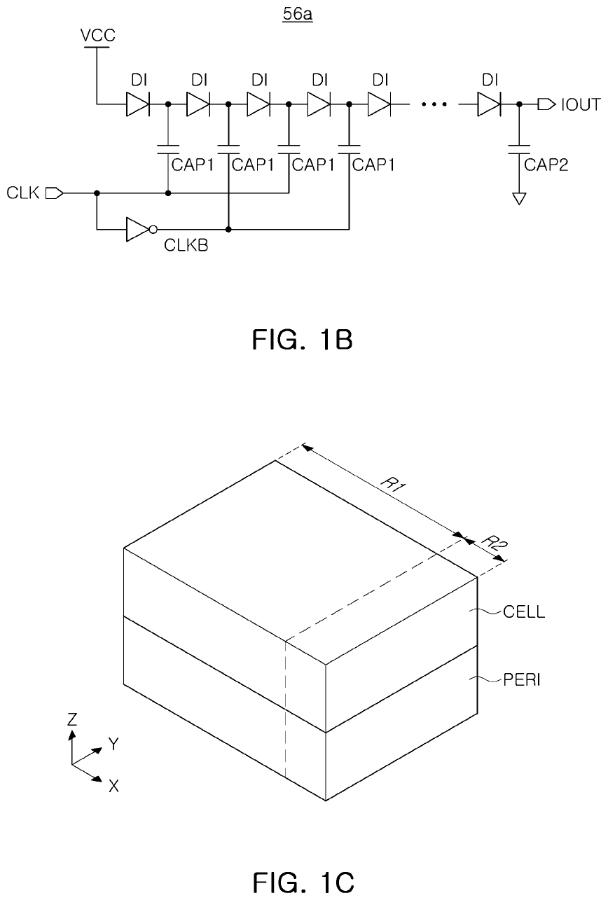

FIG. 1A is a block diagram illustrating a semiconductor device according to some example embodiments.

Referring to FIG. 1A, a semiconductor device 10 may include a memory cell array 20 and a peripheral circuit 30. The semiconductor device 10 may be configured as a memory device, for example, a nonvolatile memory such as a flash memory, or a volatile memory such as dynamic random access memory (DRAM), static random access memory (SRAM), or the like.

The memory cell array 20 may include a plurality of memory cells. The plurality of memory cells may be connected to a row decoder 33 through a plurality of word lines WL and may be connected to a read/write circuit 35 through bit lines BL. In some example embodiments, a plurality of memory cells arranged along the same row may be connected to the same word line WL, and a plurality of memory cells arranged along the same column may be connected to the same bit line BL. In some example embodiments, a plurality of memory blocks may be included, and each of the memory blocks may include a plurality of memory cells.

The peripheral circuit 30 may receive an address ADDR, command CMD, and control signal CTRL from an external entity of the semiconductor device 10, and may transmit and receive data DATA to and from external devices of the semiconductor device 10. The peripheral circuit 30 may include a row decoder 33, a read/write circuit 35, control logic (e.g., circuitry) 37, and a voltage generator 38 generating various voltages required for operation. In some example embodiments, the peripheral circuit 30 may further include various sub-circuits, such as an input/output circuit and an error correction circuit for correcting errors in data DATA read out from the memory cell array 20.

The control logic 37 may be connected to the row decoder 33, the voltage generator 38, and the input/output circuit (not shown). The control logic 37 may control overall operations of the semiconductor device 10. The control logic 37 may generate various internal control signals used in the semiconductor device 10 in response to a control signal CTRL. For example, the control logic 37 may adjust a voltage level provided by the word lines WL and the bit lines BL when memory operations such as a program operation or an erase operation are performed.

The row decoder 33 may select a portion of the plurality of memory cells in response to an address ADDR, and may select at least one word line WL. The row decoder 33 may transfer a voltage for performing a memory operation to the selected word line WL.

The read/write circuit 35 may be connected to the memory cell array 20 through the bit lines BL. The read/write circuit 35 may include a writer driver or a sense amplifier. For example, during a program operation, the read/write circuit 35 may operate as a writer driver to apply a voltage according to the data DATA to be stored in the memory cell array 20 to the bit lines BL. During a read operation, the read/write circuit 35 may operate as a sense amplifier and may detect data DATA stored in the memory cell array 20.

The voltage generator 38 may include a controller 52, an oscillator 54, and a charge pump 56.

The charge pump 56 may include a plurality of charge pumps, and each of the plurality of charge pumps may include at least one switch device and at least one pumping capacitor. The charge pump 56 may provide a current through the row decoder 33 to apply an operation voltage to the word line WL of the memory cell array.

The controller 52 may control operations of the oscillator 54. For example, the controller 52 may determine one select charge pump among the plurality of charge pumps based on at least one of PVT (process, voltage, and temperature) data of the semiconductor device 10 and a target level of a power voltage to be supplied. The controller 52 may inactivate the other charge pumps other than the select charge pump.

The oscillator 54 may output a clock signal CLK. The oscillator 54 may operate in response to the control signal VGC from the controller 52. For example, the oscillator 54 may output a clock signal CLK to at least a portion of the charge pump among the plurality of charge pumps in response to the control signal VGC transmitted by the controller 52.

FIG. 1B is a circuit diagram describing a charge pump circuit included in a voltage generator of a semiconductor device according to some example embodiments.

Referring to FIG. 1B, a charge pump circuit 56a may include a plurality of diodes DI, a plurality of pumping capacitors CAP1 and an output capacitor CAP2. The plurality of diodes DI may be connected to each other in series, and the plurality of pumping capacitors CAP1 may be connected to a node between the plurality of diodes DI. The first diode may receive a power voltage VCC having a desired (and/or alternatively predetermined) level, and the last diode may send out the output current IOUT to the output node.

Each of the plurality of pumping capacitors CAP1 may be charged or discharged by a clock signal CLK or a complementary clock signal CLKB phase-converted to have an opposite phase to that of the clock signal CLK by an inverter. For example, odd-numbered pumping capacitors CAP1 may be charged or discharged by the clock signal CLK, and even-numbered pumping capacitors CAP1 may be charged or discharged by the complementary clock signal CLKB.

FIG. 1C is a perspective diagram illustrating a semiconductor device according to some example embodiments.

Referring to FIG. 1C, the semiconductor device 10 may include a peripheral circuit structure PERI, which may be the first semiconductor structure, and a memory cell structure CELL, which may be the second semiconductor structure. The memory cell structure CELL may be disposed on the peripheral circuit structure PERI. The memory cell structure CELL may be configured as a region in which the memory cell array 20 in FIG. 1A is disposed, and the peripheral circuit structure PERI may be configured as a region in which the peripheral circuit 30 in FIG. 1A is disposed. In some example embodiments, alternatively, the memory cell structure CELL may be disposed below the peripheral circuit structure PERI.

The memory cell structure CELL may include a first region R1 and a second region R2.

The first region R1 of the memory cell structure CELL may be configured as a region in which the memory cell array 20 is disposed. The second region R2 of the memory cell structure CELL may correspond to a region for electrically connecting the memory cells of the memory cell array 20 to the peripheral circuit 30. The second region R2 may be disposed on least one end of the first region R1 in at least one direction, for example, the first direction (X-direction).

The plurality of pumping capacitors CAP1 included in the charge pump circuits 56 and 56a in FIGS. 1A and 1B may be disposed in the peripheral circuit structure PERI. For example, the plurality of pumping capacitors CAP1 may be disposed below the second region R2 of the memory cell structure CELL in the peripheral circuit structure PERI, but some example embodiments thereof are not limited thereto. In some example embodiments, a plurality of pumping capacitors CAP1 may be disposed below the first region R1 of the memory cell structure CELL.

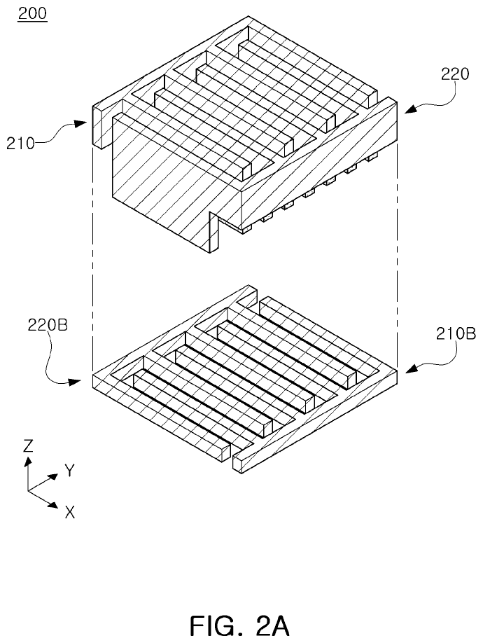

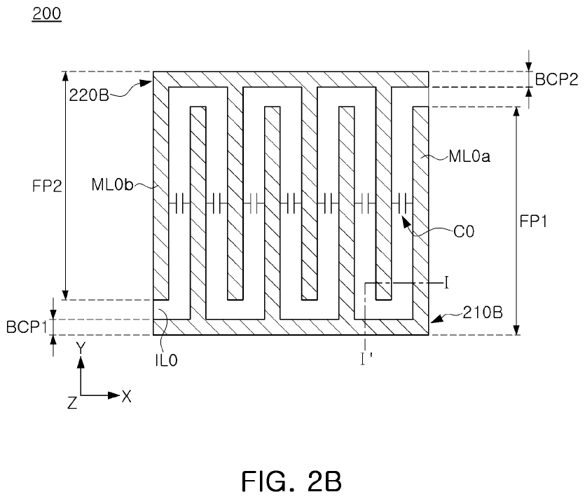

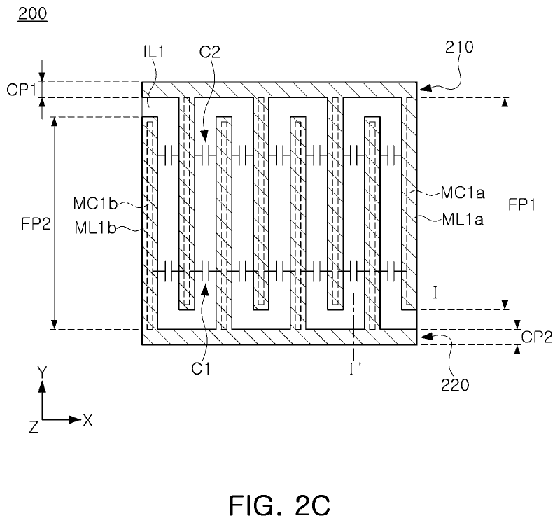

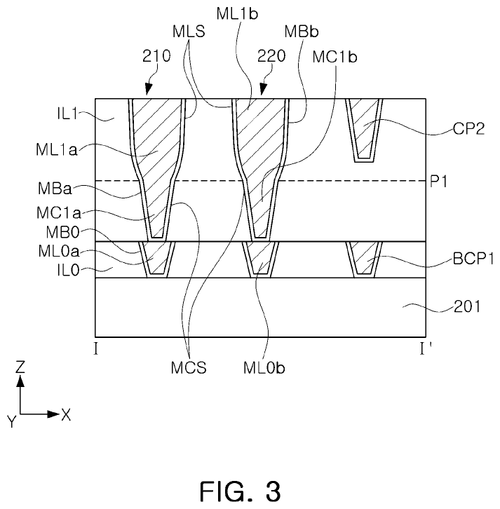

FIG. 2A is a perspective diagram describing a capacitor structure of a semiconductor device according to some example embodiments. FIG. 2B is a plan diagram describing first and second lower electrode structures of a capacitor structure in FIG. 2A according to some example embodiments. FIG. 2C is a plan diagram describing first and second electrode structures of a capacitor structure in FIG. 2A according to some example embodiments. FIG. 3 is a cross-sectional diagram describing a capacitor structure in FIGS. 2B and 2C taken along line I-I′.

Referring to FIGS. 2A to 3, a capacitor structure 200 may include first and second lower electrode structures 210B and 220B, the first and second electrode structures 210 and 220 disposed on first and second lower electrode structures 210B and 220B, a first insulating layer IL0 disposed between the first and second lower electrode structures 210B and 220B, and a second insulating layer IL1 disposed between the first and second electrode structures 210 and 220.

The capacitor structure 200 may form the pumping capacitor CAP1 of the charge pump circuit 56 and 56a described above with reference to FIGS. 1A to 1C.

The first and second lower electrode structures 210B and 220B may be disposed on the substrate 201. The first lower electrode structure 210B and the second lower electrode structure 220B may have different potentials.

The first lower electrode structure 210B may include a first lower connection portion BCP1 connecting first lower electrodes ML0a and first lower electrodes ML0a to each other and extending in the first direction (X-direction). The first lower electrodes ML0a may have a line shape protruding and extending from the first lower connection portion BCP1 in the second direction (Y-direction). The first lower electrodes ML0a may be included in the first finger portion FP1 branched from the first lower connection portion BCP1.

The second lower electrode structure 220B may include a second lower connection portion BCP2 connecting the second lower electrodes ML0b and the second lower electrodes ML0b to each other and extending in the first direction (X-direction). The second lower electrodes ML0b may have a line shape protruding and extending in the second direction (Y-direction) from the second lower connection portion BCP2. The second lower electrodes ML0b may be included in a second finger portion FP2 branched from the second lower connection portion BCP2.

The second lower electrodes ML0b may be disposed alternately with the first lower electrodes ML0a. The second lower connection portion BCP2 may be spaced apart from the first lower connection portion BCP1 in the second direction (Y-direction). In some example embodiments, a barrier conductive film MB0 may be disposed between the first lower electrodes ML0a and the first insulating layer IL0 and between the second lower electrodes ML0b and the first insulating layer IL0. For example, the barrier conductive film MB0 may extend to a side surface and a bottom surface of the first lower electrodes ML0a and may extend to a side surface and a bottom surface of the second lower electrodes ML0b.

The first insulating layer IL0 disposed between the first lower electrodes ML0a, the second lower electrodes ML0b, the first lower electrodes ML0a and second lower electrodes ML0b may constitute or form a capacitor. The capacitor formed by the first lower electrodes ML0a, the second lower electrodes ML0b and the first insulating layer IL0 may have capacitance C0.

The first and second electrode structures 210 and 220 may be disposed on the first and second lower electrode structures 210B and 220B. The first electrode structure 210 and the second electrode structure 220 may have different potentials. In some example embodiments, the first electrode structure 210 may be referred to as a first intermediate electrode structure, and the second electrode structure 220 may be referred to as a second intermediate electrode structure.

The first electrode structure 210 may include first electrodes MC1a and ML1a and a first connection portion CP1 connecting the first electrodes MC1a and ML1a to each other and extending in the first direction (X-direction). The first electrodes MC1a and ML1a may have a line shape protruding and extending from the first connection portion CP1 in the second direction (Y-direction). The first electrodes MC1a and ML1a may be included in the first finger portion FP1 branching from the first connection portion CP1. In some example embodiments, the first electrodes MC1a and ML1a may overlap the first lower electrodes ML0a of the first lower electrode structure 210B in the vertical direction (Z-direction). The first connection portion CP1 may overlap the second lower connection portion BCP2 of the second lower electrode structure 220B in the vertical direction (Z-direction).

The second electrode structure 220 may include second electrodes MC1b and ML1b and a second connection portion CP2 connecting the second electrodes MC1b and ML1b and extending in the first direction (X-direction) to each other. The second electrodes MC1b and ML1b may have a line shape protruding and extending from the second connection portion CP2 in the second direction (Y-direction). The second electrodes MC1b and ML1b may form a second finger portion FP2 branching from the second connection portion CP2. The second electrodes MC1b and ML1b may overlap the second lower electrodes ML0b of the second lower electrode structure 220B in the vertical direction (Z-direction). The second connection portion CP2 may overlap the first lower connection portion BCP1 of the first lower electrode structure 210B in the vertical direction (Z-direction).

The second electrodes MC1b and ML1b may be disposed alternately with the first electrodes MC1a and ML1a in the first direction (X-direction). The second connection portion CP2 may be spaced apart from the first connection portion CP1 in the second direction (Y-direction). The first electrodes MC1a and ML1a and the second electrodes MC1b and ML1b may include a conductive material, for example, a metal such as tungsten (W), titanium (Ti), tantalum (Ta), copper (Cu), and aluminum (Al), but some example embodiments thereof are not limited thereto.

The first electrodes MC1a and ML1a and the second electrodes MC1b and ML1b may include first wall patterns MC1a and MC1b, and second wall patterns ML1a and ML1b extending from first wall patterns MC1a and MC1b, respectively. In some example embodiments, the first wall patterns MC1a and MC1b may include a 1-1 wall pattern MC1a disposed on the first lower electrode ML0a and a 1-2 wall pattern MC1b disposed on the second lower electrode ML0b.

The first wall patterns MC1a and MC1b may include a first side surface MCS, and the second wall patterns ML1a and ML1b may include a second side surface MLS extending from the first side surface MCS. The first wall patterns MC1a and MC1b may have a width in the first direction (X-direction) increasing linearly in the vertical direction (Z-direction). The first side surface MCS may have a linear shape in the vertical direction (Z-direction). The second wall patterns ML1a and ML1b may have a width in the first direction (X-direction), with the second side surface MCS extending from the first side surface MCS and the width widening nonlinearly in the vertical direction (Z-direction). The second side surface MLS may have a curved shape. In some example embodiments, a side surface profile at a boundary point P1 between the first side surface MCS and the second side surface MLS may change nonlinearly.

The first wall patterns MC1a and MC1b and the second wall patterns ML1a and ML1b may have a line shape extending in the second direction (Y-direction) and may be formed by a dual damascene process.

A bottom surface of the first wall patterns MC1a and MC1b, the first side surface MCS, and the second side surface MLS of the second wall patterns ML1a and ML1b may be covered by the first barrier conductive films MBa and MBb. The 1-1 barrier conductive film MBa may extend along the bottom surface of the 1-1 wall pattern MC1a, the first side surface MCS of the 1-1 wall pattern MC1a, and the second side surface MLS of the 2-1 wall pattern ML1a. The 1-2 barrier conductive film MBb may extend along the bottom surface of the 1-2 wall pattern MC1b, the first side surface MCS of the 1-2 wall pattern MC1b, and the second side surface MLS of the 2-2 wall pattern ML1b.

The first wall patterns MC1a and MC1b may be integrated with the second wall patterns ML1a and ML1b.

The insulating layers IL0 and IL1 may be configured as an insulating layer including an insulating material, for example, silicon oxide, silicon nitride, silicon carbide, or silicon oxynitride.

The barrier conductive films MB0, MBa, and MBb may include at least one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN) and combinations thereof, but some example embodiments thereof are not limited thereto.

The capacitor formed by the 1-1 wall pattern MC1a and the 1-2 wall pattern MC1b and the second insulating layer IL1 may have a first capacitance C1. The capacitor formed by the 2-1 wall pattern ML1a, the 2-2 wall pattern ML1b and the second insulating layer IL1 may have a second capacitance C2. The second capacitance C2 may be larger than the first capacitance C1.

A height of the first connection portion CP1 and the second connection portion CP2 in the vertical direction (Z-direction) may be smaller than a height of the first electrodes MC1a and ML1a and second electrodes MC1b and ML1b in the vertical direction (Z-direction). In some example embodiments, a lower surface of the first connection portion CP1 and a lower surface of the second connection portion CP2 may be disposed on a level higher than a level of lower surfaces of the first wall patterns MC1a and MC1b. The lower surface of the first connection portion CP1 and the lower surface of the second connection portion CP2 may be disposed on a level higher than a level of the boundary point P1 at which the first side surface MCS of the first wall pattern MC1a and MC1b and the second side surface MLS of the second wall pattern ML1a and ML1b meet, but some example embodiments thereof are not limited thereto, and the lower surface of the first connection portion CP1 and the lower surface of the second connection portion CP2 may be disposed and/or formed on the same level as a level of the boundary point P1.

A semiconductor device according to some example embodiments may include a capacitor structure 200 including first electrodes MC1a and ML1a and second electrodes MC1b and ML1b, and the first electrodes MC1a and ML1a and the second electrodes MC1b and ML1b may include first wall pattern MC1a and MC1b and the second wall pattern ML1a and ML1b on first wall pattern MC1a and MC1b. As the first wall pattern MC1a and MC1b and second wall pattern ML1a and ML1b are formed by a dual damascene process, the line width roughness (LWR) of the first electrodes MC1a and ML1a and the second electrodes MC1b and ML1b may be improved.

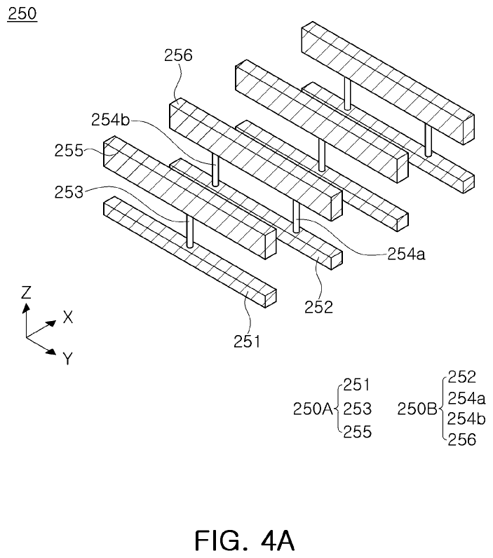

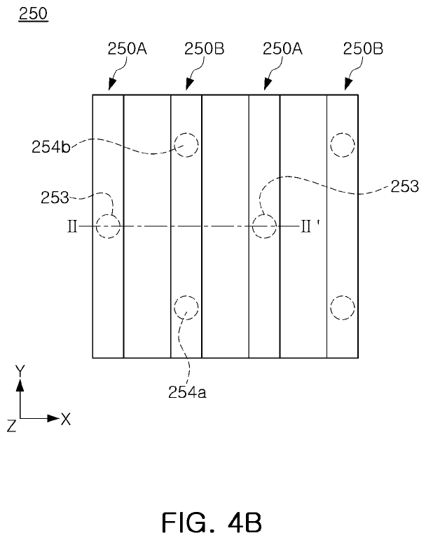

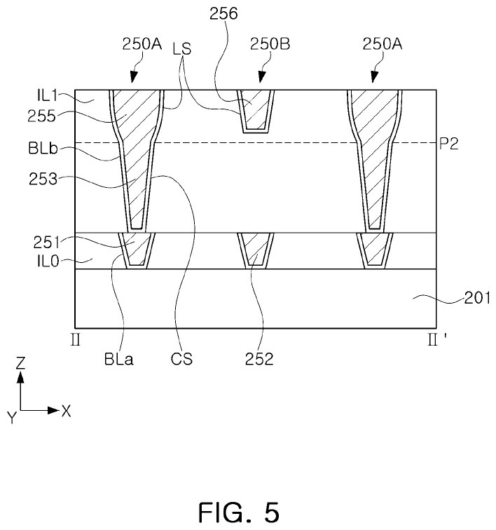

FIG. 4A is a perspective diagram describing a lower interconnection structure of a semiconductor device according to some example embodiments. FIG. 4B is a plan diagram describing a lower interconnection structure in FIG. 4A according to some example embodiments. FIG. 5 is a cross-sectional diagram describing a lower interconnection structure in FIG. 4B taken along line II-II′ according to some example embodiments.

Referring to FIGS. 4A, 4B, and 5, a lower interconnection structure 250 may be disposed below the first region R1 of the memory cell structure CELL in the peripheral circuit structure PERI described above with reference to FIG. 1C. The lower interconnection structure 250 may be spaced apart from the capacitor structure 200 disposed below the second region R2 of the memory cell structure CELL in the peripheral circuit structure PERI in the first direction (X-direction).

The lower interconnection structure 250 may include a first interconnection structure 250A and a second interconnection structure 250B. The first interconnection structure 250A may be disposed alternately with the second interconnection structure 250B in the first direction (X-direction).

The first interconnection structure 250A may include a first lower interconnection 251 extending in the second direction (Y direction), a first peripheral contact plug 253 disposed on the first lower interconnection 251, and a first peripheral interconnection 255 disposed on the first peripheral contact plug 253 and extending in the second direction (Y-direction).

The second interconnection structure 250B may include a second lower interconnection 252 extending in the second direction (Y-direction), second peripheral contact plug 254a and 254b disposed on the second lower interconnection 252, and a second peripheral interconnection 256 disposed on the second peripheral contact plug 254a and 254b and extending in the second direction (Y-direction).

The second lower interconnection 252 may be disposed on the same level as a level of the first lower interconnection 251. A bottom surface and a side surface of the first lower interconnection 251 and a bottom surface and a side surface of the second lower interconnection 252 may be covered by the barrier conductive film BLa.

The first peripheral contact plug 253 may be disposed on the same level as a level of the second peripheral contact plugs 254a and 254b.

The first and second lower interconnections 251 and 252 may have a line shape extending in the second direction (Y-direction). The first peripheral contact plug 253 and the second peripheral contact plug 254a and 254b may have a cylindrical shape as a contact structure. The first peripheral contact plug 253 and the second peripheral contact plug 254a and 254b may have a via hole shape. The first peripheral interconnection 255 and the second peripheral interconnection 256 may have a line shape extending in the second direction (Y-direction).

The first peripheral contact plug 253 may be disposed in a central region on the first lower interconnection 251 between the first lower interconnection 251 and the first peripheral interconnection 255. However, some example embodiments thereof are not limited thereto, and the first peripheral contact plug 253 may be disposed to intersect with the second peripheral contact plugs 254a and 254b disposed on the same level. In some example embodiments, the second peripheral contact plugs 254a and 254b may include 2-1 contact plugs 254a and 2-2 contact plugs 254b spaced apart from each other in the second direction (Y-direction) on the second lower interconnection 252.

A height of the first and second peripheral interconnections 255 and 256 in the vertical direction (Z-direction) may be higher than a height of the first and second lower interconnections 251 and 252 in the vertical direction (Z-direction).

A width of the first peripheral contact plug 253 may increase linearly in the vertical direction (Z-direction). The first peripheral contact plug 253 may have a third side surface CS, and the third side surface CS may have a side surface having a cylindrical shape.

The first peripheral interconnection 255 may have a fourth side surface LS extending from an upper surface of the first peripheral contact plug 253 and a third side surface CS of the first peripheral contact plug 253. In some example embodiments, the second peripheral contact plugs 254a and 254b may have a third side surface CS similarly to the first peripheral contact plug 253, and the second peripheral interconnection 256 may have a fourth side surface LS in contact with an upper surface of the second peripheral contact plugs 254a and 254b and extending from the third side surface CS of the second peripheral contact plugs 254a and 254b.

A side surface profile may change nonlinearly at a boundary point P2 at which the third side surface CS of the first peripheral contact plug 253 and the fourth side surface LS of the first peripheral interconnection 255 meet. Similarly, the side surface profile may change nonlinearly at the boundary point P2 at which the third side surface CS of the second peripheral contact plug 254 and the fourth side surface LS of the second peripheral interconnection 256 meet.

The first peripheral contact plug 253 and the first peripheral interconnection 255 may be provided and/or formed by a dual damascene process. The second peripheral contact plugs 254a and 254b and the second peripheral interconnection 256 may also be provided and/or formed by a dual damascene process.

The upper surface of the first peripheral interconnection 255 and the upper surface of the second peripheral interconnection 256 may be disposed on the same level as a level of an upper surface of the second wall patterns ML1a and ML1b in FIG. 3. In some example embodiments, a depth from the upper surface of the first peripheral interconnection 255 and the upper surface of the second peripheral interconnection 256 to the boundary point P2 at which the third side surface CS and the fourth side surface LS meet may be smaller than a depth from the upper surface of second wall pattern ML1a and ML1b in FIG. 3 to the boundary point P1 at which the first side surface MCS and the second side surface MLS meet.

The semiconductor device according to some example embodiments may include a capacitor structure and a lower interconnection structure 250 spaced apart from in the first direction (X-direction), the lower interconnection structure 250 may include peripheral contact plugs 253, 254a and 254b and first and second peripheral interconnections 255, 256 on the peripheral contact plug 253, 254a and 254b, and the first peripheral contact plug 253, the first peripheral interconnection 255, the second peripheral contact plug 254a and 254b and the second peripheral interconnection 256 may be formed by a dual damascene process. Accordingly, a lower interconnection structure 250 having improved reliability may be provided by reducing misalignment of the first and second peripheral interconnections 255 and 256.

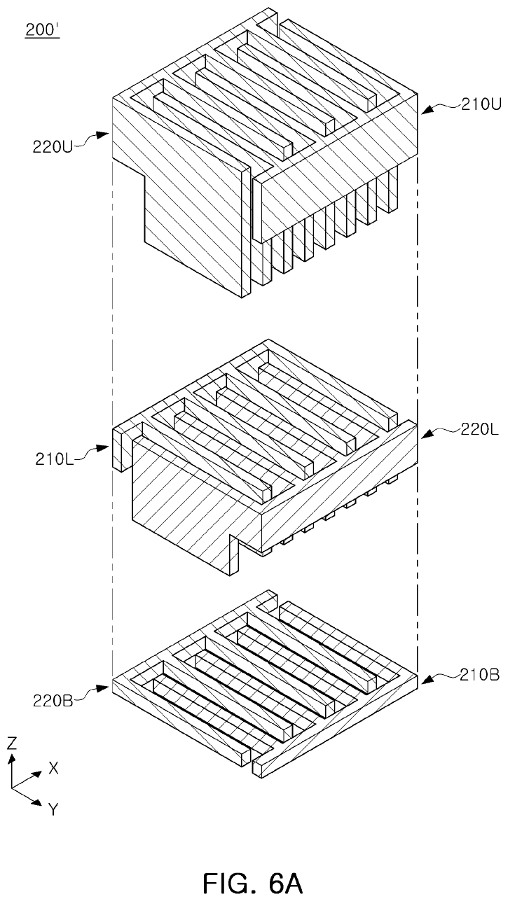

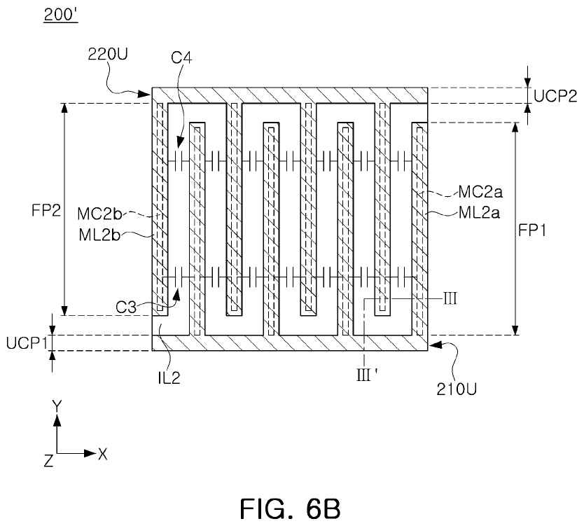

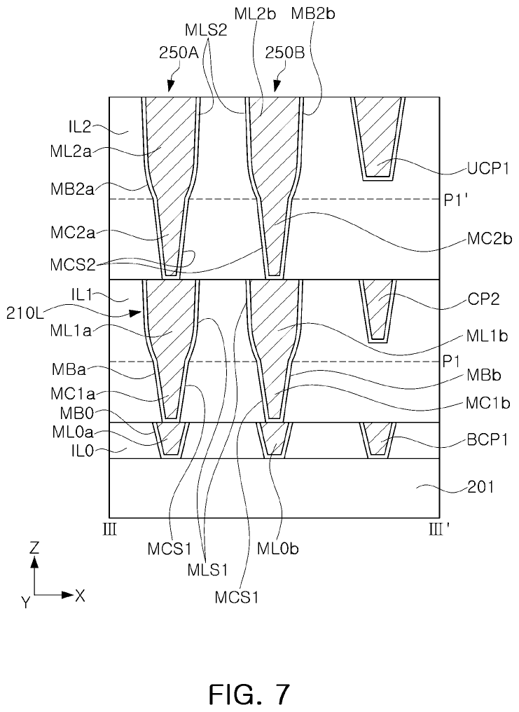

FIG. 6A is a perspective diagram describing a capacitor structure of a semiconductor device according to some example embodiments. FIG. 6B is a plan diagram describing first and second upper electrode structures of a capacitor structure in FIG. 6A according to some example embodiments. FIG. 7 is a cross-sectional diagram describing a capacitor structure in FIG. 6B taken along line III-III′ according to some example embodiments.

Referring to FIG. 6A, the components other than the first and second upper electrode structures 210U and 220U of the capacitor structure 200′ may be the same as or similar to the components of the capacitor structure 200 in FIG. 2A.

Referring to FIGS. 6A to 7, the capacitor structure 200′ may include first and second lower electrode structures 210B and 220B, first and second intermediate electrode structures 210L and 220L disposed on the first and second lower electrode structures 210B and 220B, first and second upper electrode structures 210U and 220U, disposed on the first and second intermediate electrode structures 210L and 220L, a first insulating layer IL0 disposed between the first and second lower electrode structures 210B and 220B, a second insulating layer IL1 disposed between the first and second intermediate electrode structures 210L and 220L, and a third insulating layer IL2 disposed between the first and second upper electrode structures 210U and 220U.

The first and second lower electrode structures 210B and 220B may correspond to the first and second lower electrode structures 210B and 220B of the capacitor structure 200 in FIG. 2B. The first and second intermediate electrode structures 210L and 220L may correspond to the first and second electrode structures 210 and 220 of the capacitor structure 200 in FIG. 2C.

The first and second upper electrode structures 210U and 220U may be disposed on the first and second intermediate electrode structures 210L and 220L. The first upper electrode structure 210U and the second upper electrode structure 220U may have different potentials.

The first upper electrode structure 210U may include first upper electrodes MC2a and ML2a and a first upper connection portion UCP1 connecting first upper electrodes MC2a and ML2a to each other and extending in the first direction (X-direction). The first upper electrodes MC2a and ML2a may have a line shape protruding and extending from the first upper connection portion UCP1 in the second direction (Y-direction). The first upper electrodes MC2a and ML2a may form the first finger portion FP1 branching from the first upper connection portion UCP1. In some example embodiments, the first upper electrodes MC2a and ML2a may overlap the first electrodes MC1a and ML1a of the first intermediate electrode structure 210L and the first lower electrode ML0a of the first lower electrode structure 210B in the vertical direction (Z-direction). The first upper connection portion UCP1 may overlap the second connection portion CP2 of the second intermediate electrode structure 220L and the first lower connection portion BCP1 of the first lower electrode structure 210B in the vertical direction (Z-direction).

The second upper electrode structure 220U may include second upper electrodes MC2b and ML2b and a second upper connection portion UCP2 connecting the second upper electrodes MC2b and ML2b to each other and extending in the first direction (X-direction). The second upper electrodes MC2b and ML2b may have a line shape protruding and extending from the second upper connection portion UCP2 in the second direction (Y-direction). The second upper electrodes MC2b and ML2b may form a second finger portion FP2 branched from the second upper connection portion UCP2. In some example embodiments, the second upper electrodes MC2b and ML2b may overlap the second electrodes MC1b and ML1b of the second intermediate electrode structure 220L and the second lower electrode ML0b of the second lower electrode structure 220B in the vertical direction (Z-direction). The second upper connection portion UCP2 may overlap the first connection portion CP1 of the first intermediate electrode structure 210L and the second lower connection portion BCP2 of the second lower electrode structure 220B in the vertical direction (Z-direction).

The first upper electrodes MC2a and ML2a and the second upper electrodes MC2b and ML2b may be alternately disposed in the first direction (X-direction). The first upper connection portion UCP1 may be spaced apart from the second upper connection portion UCP2 in the second direction (Y-direction). The first upper electrodes MC2a and ML2a and the second upper electrodes MC2b and ML2b may include a conductive material.

The first upper electrodes MC2a and ML2a and the second upper electrodes MC2b and ML2b may include the third wall patterns MC2a and MC2b and the fourth wall patterns ML2a and ML2b extending from the third wall patterns MC2a and MC2b. In some example embodiments, the third wall patterns MC2a and MC2b may be in contact with the second wall patterns ML1a and ML1b. The third wall pattern MC2a and MC2b may include a 3-1 wall pattern MC2a disposed on the 2-1 wall pattern ML1a and the 3-2 wall pattern MC2b disposed on the 2-2 wall pattern ML1b.

The first wall patterns MC1a and MC1b may include a 1-1 side surface MCS1, and the second wall patterns ML1a and ML1b may include a 2-1 side surface MLS1 extending from the 1-1 side surface MCS1.

The third wall patterns MC2a and MC2b may include a 1-2 side surface MCS2, and the fourth wall patterns ML2a and ML2b may include a 2-2 side surface MLS2 extending from the 1-2 side surface MCS1.

The first wall patterns MC1a and MC1b and the third wall patterns MC2a and MC2b may have a width linearly widening in the first direction (X-direction) in the vertical direction (Z-direction). The 1-1 side surface MCS1 and the 1-2 side surface MCS2 may have a linear shape. The second wall patterns ML1a and ML1b and the fourth wall patterns ML2a and ML2b may have a width nonlinearly widening in the first direction (X-direction) in the vertical direction (Z-direction). The 2-1 side surface MLS1 and the 2-2 side surface MLS2 may have a curved shape.

The side surface profile may change nonlinearly at a boundary point P1 of the 1-1 side surface MCS1 and the 2-1 side surface MLS1 and a boundary point P1′ of the 1-2 side surface MCS2 and the 2-2 side surface MLS2.

A height of the third wall patterns MC2a and MC2b in the vertical direction (Z-direction) may be greater than a height of the first wall patterns MC1a and MC1b in the vertical direction (Z-direction). However, some example embodiments thereof are not limited thereto, and a height of the third wall patterns MC2a and MC2b in the vertical direction (Z-direction) may be substantially the same as a height of the first wall pattern MC1a and MC1b in the vertical direction (Z-direction).

A height of the fourth wall patterns ML2a and ML2b in the vertical direction (Z-direction) may be greater than a height of the second wall patterns ML1a and ML1b in the vertical direction (Z-direction). In some example embodiments, a width in the first direction (X-direction) at an upper surface of the second wall patterns ML1a and ML1b may be substantially the same as a width in the first direction (X-direction) at an upper surface of the fourth wall patterns ML2a and ML2b.

The third wall patterns MC2a and MC2b and the fourth wall patterns ML2a and ML2b may have a line shape extending in the second direction (Y-direction) and may be formed by a dual damascene process.

A bottom surface of the third wall pattern MC2a and MC2b, the 1-2 side surface MCS2 of the third wall pattern MC2a and MC2b, and the 2-2 side surface MLS2 of the fourth wall pattern ML2a and ML2b may be covered by the second barrier conductive film MB2a, MB2b. In some example embodiments, the 2-1 barrier conductive film MB2a may extend along the bottom surface of the 3-1 wall pattern MC2a, the 1-2 side surface MCS2 of the 3-1 wall pattern MC2a and the 2-2 side surface MLS2 of the 4-1 wall pattern ML2a. In some example embodiments, the second barrier conductive films MB2a and MB2b may include the same material as the first barrier conductive films MBa and MBb.

The capacitor formed by the 3-1 wall pattern MC2a, the 3-2 wall pattern MC2b and the third insulating layer IL2 may have third capacitance C3. The capacitor formed by the 4-1 wall pattern ML2a, the 4-2 wall pattern ML2b, and the third insulating layer IL2 may have fourth capacitance C4. The fourth capacitance C4 may be larger than the third capacitance C3.

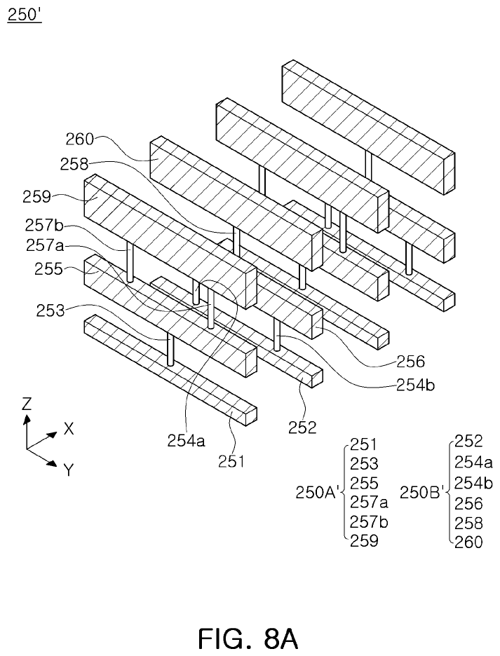

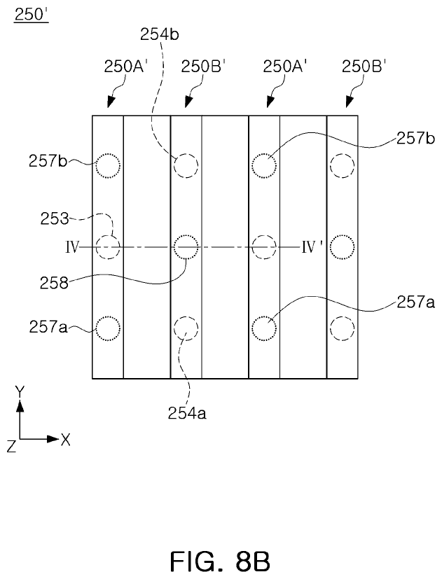

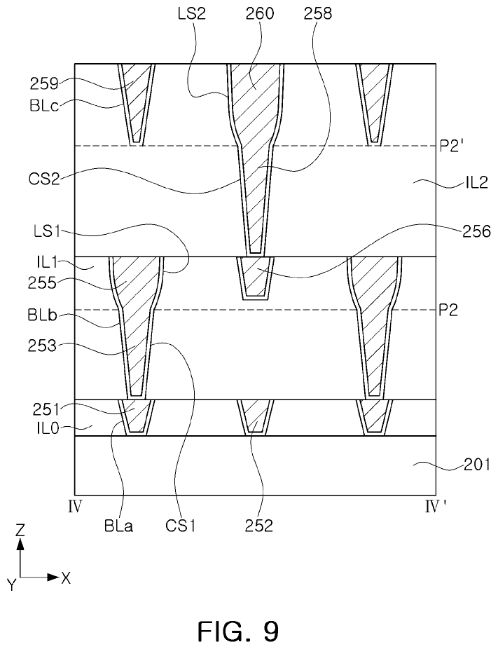

FIG. 8A is a perspective diagram a lower interconnection structure of a semiconductor device according to some example embodiments. FIG. 8B is a plan diagram a lower interconnection structure in FIG. 8A according to some example embodiments. FIG. 9 is a cross-sectional diagram describing a lower interconnection structure in FIG. 8B taken along line IV-IV′ according to some example embodiments.

Referring to FIGS. 8A, 8B, and 9, the lower interconnection structure 250′ may be disposed below the first region R1 of the memory cell structure CELL in the peripheral circuit structure PERI with reference to FIG. 1C. The lower interconnection structure 250′ may be spaced apart from the capacitor structure 200′ disposed below the second region R2 of the memory cell structure CELL in the structure PERI in the first direction (X-direction).

The lower interconnection structure 250′ may include a first interconnection structure 250A′ and a second interconnection structure 250B′. The first interconnection structure 250A′ may be disposed alternately with the second interconnection structure 250B′ in the first direction (X-direction).

The first interconnection structure 250A′ may include a first lower interconnection 251 extending in the second direction (Y direction), a first peripheral contact plug 253 disposed on the first lower interconnection 251, a first peripheral interconnection 255 disposed on the first peripheral contact plug 253 and extending in the second direction (Y-direction), a third peripheral interconnection 259 disposed on the third peripheral contact plug 257a and 257b and the third peripheral contact plug 257a and 257b on the first peripheral interconnection 255 and extending in the second direction (Y-direction).

The first interconnection structure 250A′ may be configured as an interconnection structure in which the third peripheral contact plugs 257a and 257b and the third peripheral interconnection 259 are added to the first interconnection structure 250A in FIG. 4A.

The second interconnection structure 250B′ may include a second lower interconnection 252 extending in the second direction (Y-direction), a second peripheral contact plug 254a and 254b disposed on the second lower interconnection 252, a second peripheral interconnection 256 disposed on the second peripheral contact plug 254a and 254b and extending in the second direction (Y-direction), a fourth peripheral contact plug 258 on the second peripheral interconnection 256, and a fourth peripheral interconnection 260 on the fourth peripheral contact plug 258 and extending in the second direction (Y-direction).

The second interconnection structure 250B′ may be configured as an interconnection structure in which a fourth peripheral contact plug 258 and a fourth peripheral interconnection 260 are added to the second interconnection structure 250B in FIG. 4A.

The third peripheral contact plugs 257a and 257b of the first interconnection structure 250A′ may be disposed on the same level as a level of the fourth peripheral contact plug 258 of the second interconnection structure 250B′. The third peripheral interconnection 259 and the fourth peripheral interconnection 260 may be disposed on the same level.

The third peripheral contact plug 257a and 257b and the fourth peripheral contact plug 258 may have a cylindrical shape as a contact structure. The third peripheral contact plugs 257a and 257b and the fourth peripheral contact plug 258 may have a via hole shape. The third peripheral interconnection 259 and the fourth peripheral interconnection 260 may have a line shape extending in the second direction (Y-direction).

The third peripheral contact plug 257a and 257b and the third peripheral interconnection 259 may be provided and/or formed by a dual damascene process. The fourth peripheral contact plug 258 and the fourth peripheral interconnection 260 may also be provided and/or formed by the dual damascene process.

The third peripheral contact plugs 257a and 257b may include a 3-1 peripheral contact plug 257a and a 3-2 peripheral contact plug 257b spaced apart from each other on the first peripheral interconnection 255 in the second direction (Y-direction) between the first peripheral interconnection 255 and the third peripheral interconnection 259. The fourth peripheral contact plug 258 may be disposed in a central region of the second peripheral interconnection 256 between the second peripheral interconnection 256 and the fourth peripheral interconnection 260. However, some example embodiments thereof are not limited thereto, and the fourth peripheral contact plug 258 may intersect with the third peripheral contact plugs 257a and 257b disposed on the same level.

A height of the third and fourth peripheral interconnections 259 and 260 in the vertical direction (Z-direction) may be higher than a height of the first and second peripheral interconnections 255 and 256 in the vertical direction (Z-direction).

A width of the first peripheral contact plug 253 may increase linearly in the vertical direction (Z-direction). The first peripheral contact plug 253 may have a 3-1 side surface CS1, and the 3-1 side surface CS1 may have a side surface having a cylindrical shape.

The first peripheral interconnection 255 may be in contact with the upper surface of the first peripheral contact plug 253 and may have a 4-1 side surface LS1 extending from the 3-1 side surface CS1 of the first peripheral contact plug 253.

A width of the fourth peripheral contact plug 258 may increase linearly in the vertical direction (Z-direction). The fourth peripheral contact plug 258 may have a 3-2 side surface CS2, and the 3-2 side surface CS2 may have a side surface having a cylindrical shape. The third peripheral contact plugs 257a and 257b may have a 3-1 side surface CS1 similarly to the fourth peripheral contact plug 258.

The fourth peripheral interconnection 260 may have a 4-2 side surface LS2 extending from the upper surface of the fourth peripheral contact plug 258 and extending from the 3-2 side surface CS2 of the fourth peripheral contact plug 258.

A side surface profile may change nonlinearly at a boundary point P2 at which the 3-1 side surface CS1 of the first peripheral contact plug 253 and the 4-1 side surface LS1 of the first peripheral interconnection 255 meet, and a boundary point P2′ at which the 3-2 side surface CS2 of the third peripheral contact plug 257a and 257b and the 4-2 side surface LS2 of the third peripheral interconnection 259 meet.

An upper surface of the third peripheral interconnection 259 and an upper surface of the fourth peripheral interconnection 260 may be disposed on the same level as a level of an upper surface of the fourth wall patterns ML2a and ML2b in FIG. 7. In some example embodiments, the depth from the upper surface of the third peripheral interconnection 259 and the upper surface of the fourth peripheral interconnection 260 to the boundary point P2′ at which the 3-2 side surface CS2 and the 4-2 side surface LS2 meet may be smaller than the depth from the upper surface of the fourth wall pattern ML2a and ML2b in FIG. 7 to the boundary point P2 at which the 1-2 side surface MCS2 and the 2-2 side surface MLS2 meet.

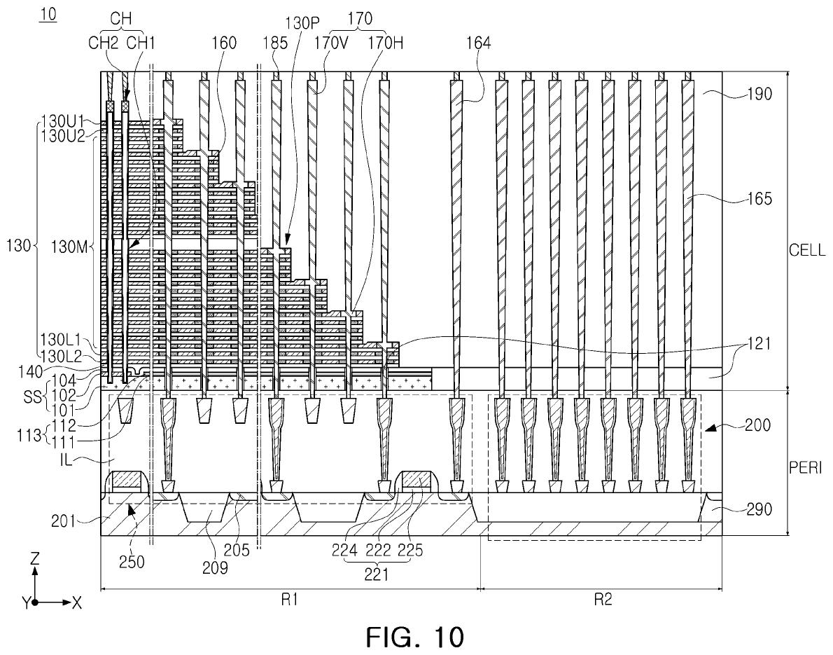

FIG. 10 is a cross-sectional diagram illustrating a semiconductor device according to some example embodiments.

Referring to FIG. 10, a semiconductor device 10 may include a peripheral circuit structure PERI including a substrate 201 and a memory cell structure CELL including a plate layer 101.

The peripheral circuit structure PERI may include a substrate 201, impurity regions 205 and device isolation regions 209 in the substrate 201, circuit devices 221 disposed on the substrate 201, a peripheral region insulating layer 290, and a lower interconnection structure 250.

The substrate 201 may have an upper surface extending in the first direction (X-direction) and the second direction (Y-direction). An active region may be defined on the substrate 201 by the isolation device regions 209. In a portion of the active region, the impurity regions 205 including impurities may be disposed. The substrate 201 may include a semiconductor material, such as a group IV semiconductor, a group III-V compound semiconductor, or a group II-VI compound semiconductor. The substrate 201 may be provided as a bulk wafer or an epitaxial layer. For example, the substrate 201 may be bulk silicon or silicon-on-insulator (SOI).

The circuit devices 221 may include a planar transistor. Each of the circuit devices 221 may include a circuit gate dielectric layer 222, a spacer layer 224, and a circuit gate electrode 225. As source/drain regions, the impurity regions 205 may be disposed in the substrate 201 on both sides of the circuit gate electrode 225.

The insulating layer IL may be disposed on the circuit device 221 on the substrate 201. The peripheral region insulating layer 290 may include a plurality of insulating layers formed in different processes. The insulating layer IL may be formed of an insulating material.

The lower interconnection structure 250 may be electrically connected to the circuit devices 221 and the impurity regions 205. The lower interconnection structure 250 may include a lower interconnection (e.g., first lower interconnection 251 in FIG. 4A), a peripheral interconnection (e.g., first peripheral interconnection 255 in FIG. 4A) and a contact plug between the lower interconnection and the peripheral interconnection (e.g., first peripheral contact plug 253 in FIG. 4A). The lower interconnection and the peripheral interconnection may have a line shape, and the contact plug may have a via hole shape. An electrical signal may be applied to the circuit device 221 by the lower interconnection structure 250. The lower interconnection structure 250 may also be connected to the circuit gate electrode 225 in a region not illustrated.

The capacitor structure 200 may be spaced apart from the lower interconnection structure 250 in the first direction (X-direction) and may be disposed on the second region R2 of the peripheral circuit structure PERI. The capacitor structure 200 may be disposed on the isolation device region 209 of the substrate 201. The capacitor structure 200 may include a lower interconnection of the lower interconnection structure 250, a peripheral interconnection, a lower electrode formed in the same process as a process of forming the peripheral contact plug disposed between the lower interconnection and the peripheral interconnection, and first and second electrodes including a first wall pattern and a second wall pattern extending from the first wall pattern.

The memory cell structure CELL may have first and second regions R1, R2, a source structure SS, gate electrodes 130 stacked on the source structure SS, interlayer insulating layers 140 alternately stacked with the gate electrodes 130, channel structures CH disposed to penetrate a stack structure of the gate electrodes 130, and contact plugs 170 connected to the gate electrodes 130 and extending vertically. The memory cell structure CELL may include a horizontal insulating layer 113 disposed below the gate electrodes 130, substrate insulating layers 121 penetrating the plate layer 101, studs 185 on the contact plugs 170, and a cell region insulating layer 190 covering the gate electrodes 130.

In the memory cell structure CELL, the first region R1 may be configured as a region in which the gate electrodes 130 are vertically stacked and form memory cells or are connected to contact plugs 170. The second region R2 may be configured as an external side region of the plate layer 101.

The source structure SS may include the plate layer 101, the first horizontal conductive layer 102, and the second horizontal conductive layer 104 stacked in order. The plate layer 101 may have a plate shape and may function as at least a portion of a common source line of the semiconductor device 100. The plate layer 101 may include a conductive material, for example, a semiconductor material. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be stacked in order on the upper surface of the plate layer 101 in the region in which the channel structures CH are disposed. The first horizontal conductive layer 102 may function as a portion of the common source line of the semiconductor device 100, for example, may function as a common source line together with the plate layer 101. The first horizontal conductive layer 102 may be directly connected to the channel layer in the channel structure CH. The first and second horizontal conductive layers 102 and 104 may include a semiconductor material, for example, polycrystalline silicon.

The horizontal insulating layer 113 may be disposed on the plate layer 101 on the same level as a level of the first horizontal conductive layer 102. The horizontal insulating layer 113 may include first and second horizontal insulating layers 111 and 112 alternately stacked on the plate layer 101. The horizontal insulating layer 113 may be layers which remain after a portion thereof are replaced with the first horizontal conductive layer 102 in the process of manufacturing of the semiconductor device 100. The horizontal insulating layer 113 may include silicon oxide, silicon nitride, silicon carbide, or silicon oxynitride. The first horizontal insulating layers 111 and the second horizontal insulating layer 112 may include different insulating materials.

The substrate insulating layers 121 may be disposed to penetrate the plate layer 101, the horizontal insulating layer 113, and the second horizontal conductive layer 104. The substrate insulating layer 121 may include an insulating material, for example, silicon oxide, silicon nitride, silicon carbide, or silicon oxynitride.

The gate electrodes 130 may be vertically stacked and spaced apart from each other on the plate layer 101 and may form a stack structure together with the interlayer insulating layers 140. The stack structure may include lower and upper stack structures vertically stacked. The gate electrodes 130 may include first upper gate electrodes 130U1 and 130U2 forming string select transistors, memory gate electrodes 130M forming a plurality of memory cells, and second lower gate electrodes 130L1 and 130L2 forming a ground select transistor. The number of the memory gate electrodes 130M included in the memory cells may be determined depending on capacity of the semiconductor device 100.

The gate electrodes 130 may be vertically stacked and spaced apart from each other on the first region R1, may extend to different lengths in the X-direction and may form step structures in the form of a staircase. Due to the stepped structure, the gate electrodes 130 in the lower portion may extend longer than the gate electrode 130 in the upper portion, and the gate electrodes 130 may have contact regions 130P exposed upwardly from the interlayer insulating layers 140, respectively. The gate electrodes 130 may be connected to the contact plugs 170 in the contact regions 130P, which may be end regions.

The gate electrodes 130 may include a metal material, such as tungsten (W). In some example embodiments, the gate electrodes 130 may include polycrystalline silicon or metal silicide material. The gate electrodes 130 may include the same material entirely. In some example embodiments, the gate electrodes 130 may further include a diffusion barrier, for example, the diffusion barrier may include tungsten nitride (WN), tantalum nitride (TaN), titanium nitride (TiN), or a combination thereof.

The interlayer insulating layers 140 may be disposed between the gate electrodes 130. Similarly to the gate electrodes 130, the interlayer insulating layers 140 may be spaced apart from each other in a direction perpendicular to an upper surface of the plate layer 101 and may extend in the first direction (X-direction). The interlayer insulating layers 140 may include an insulating material such as silicon oxide or silicon nitride.

The channel structures CH may penetrate the gate electrodes 130, may extend in the vertical direction (Z-direction), and may be connected to the plate layer 101. The channel structures CH may form a memory cell string and may be spaced apart from each other in rows and columns on the plate layer 101. The channel structures CH may be disposed to form a grid pattern on the X-Y plane or in a zigzag pattern in one direction. The channel structures CH may have a pillar shape and may have an inclined side surface having a width decreasing toward the plate layer 101.

The channel structures CH may include lower and upper channel structures CH1 and CH2 vertically stacked. The channel structures CH may have a form in which the lower channel structures CH1 and the upper channel structures CH2 are connected to each other, and may have a bent portion due to a difference in width in the connection region. However, in some example embodiments, the number of channel structures stacked in the vertical direction (Z-direction) may vary. Each of the channel structures CH may include a channel layer disposed in the channel hole, a gate dielectric layer, a channel filling insulating layer, and a channel pad on an upper end.

Contact plugs 170 may be connected to contact regions 130P of the gate electrodes 130. The contact plugs 170 may penetrate at least a portion of the cell region insulating layer 190 and may be connected to the contact regions 130P of the gate electrodes 130 exposed in an upper portion, respectively. The contact plugs 170 may penetrate the gate electrodes 130 below the contact regions 130P, may penetrate the second horizontal conductive layer 104, the horizontal insulating layer 113, and the plate layer 101, and may be connected to the lower interconnection structure 250 in the peripheral circuit structure PERI.

The contact plugs 170 may be spaced apart from the gate electrodes 130 below the contact regions 130P by the contact insulating layers 160. The contact plugs 170 may be spaced apart from the plate layer 101, the horizontal insulating layer 113, and the second horizontal conductive layer 104 by the substrate insulating layers 121.

Each of the contact plugs 170 may have a horizontally extending form in the contact region 130P. The contact plug 170 may include a vertical extension portion 170V extending in a vertical direction (Z-direction) and a horizontal extension portion 170H extending horizontally from the vertical extension portion 170V and in contact with the gate electrode 130. The horizontal extension portion 170H may be disposed along the circumference of the vertical extension portion 170V, and the entire side surface thereof may be surrounded by the gate electrode 130. The contact plugs 170 may be spaced apart from the gate electrodes 130 below the contact regions 130P, that is, the gate electrodes 130 not electrically connected to each other, by the contact insulating layers 160.

The contact plugs 170 may include at least one of a conductive material, for example, tungsten (W), copper (Cu), aluminum (Al), and alloys thereof. In some example embodiments, the contact plugs 170 may include a barrier layer extending along the side surface and the bottom surface, or may have an air gap therein.

The contact insulating layers 160 may be disposed to surround the side surfaces of the contact plugs 170 below the contact regions 130P. The contact insulating layers 160 may be spaced apart from each other in the vertical direction (Z-direction) around each of the contact plugs 170. The contact insulating layers 160 may be disposed on substantially the same level as a level of the gate electrodes 130. The contact insulating layers 160 may include an insulating material, for example, silicon oxide, silicon nitride, or silicon oxynitride.

The studs 185 may form a cell interconnection structure electrically connected to memory cells in the memory cell structure CELL. The studs 185 may be connected to the channel structures CH and the contact plugs 170, and may be electrically connected to the channel structures CH and the gate electrodes 130. The studs 185 may include a metal, for example, tungsten (W), copper (Cu), aluminum (Al), or the like.

The cell region insulating layer 190 may be disposed to cover the stack structure of the gate electrodes 130 and the contact plugs 170. The cell region insulating layer 190 may be formed of an insulating material and may include a plurality of insulating layers.

The through-plug 164 and the capacitor contacts 165 may be disposed in the second region R2 of the memory cell region CELL, which may be the external side region of the plate layer 101, and may extend to the peripheral circuit region PERI by penetrating the cell region insulating layer 190. The through-plug 164 and the capacitor contacts 165 may be disposed to be connected to the studs 185 of the memory cell region CELL and the lower interconnection structure 250 of the peripheral circuit region PERI. The through-plug 164 and the capacitor contacts 165 may include a conductive material, for example, a metal material such as tungsten (W), copper (Cu), and aluminum (Al). The through-plug 164 and the capacitor contacts 165 may be formed in the same process as a process of forming the contact plugs 170, may include the same material, and may have the same internal structure.

The capacitor structure 200 may be disposed in the second region R2, and may be disposed throughout the peripheral circuit region PERI and the memory cell region CELL. The capacitor structure 200 may perform a function of storing electric charges. The capacitor structure 200 may include a first electrode structure 210, a second electrode structure 220, and an insulating layer IL (e.g., see FIG. 3). The capacitor structure 200 may be disposed on the device isolation region 209 and may vertically overlap the device isolation region 209.

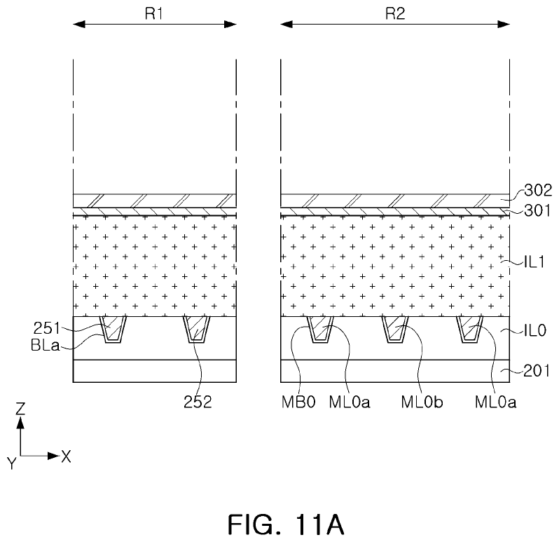

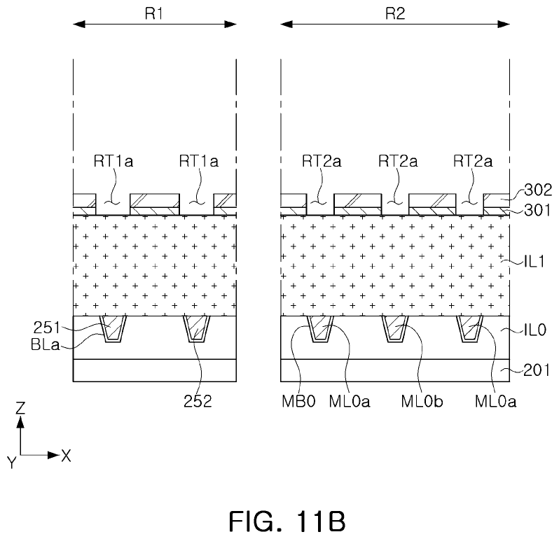

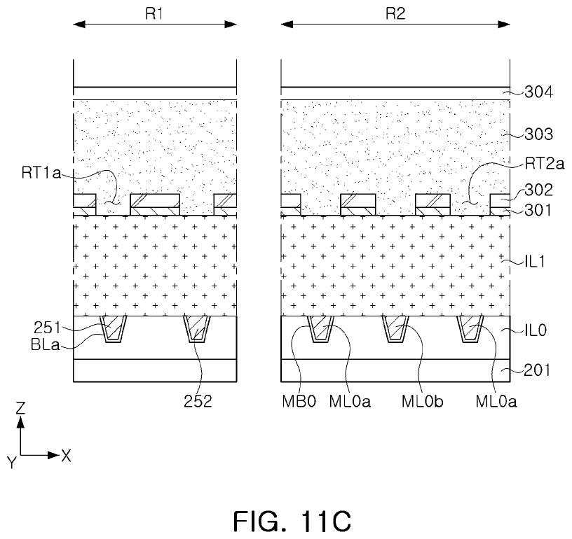

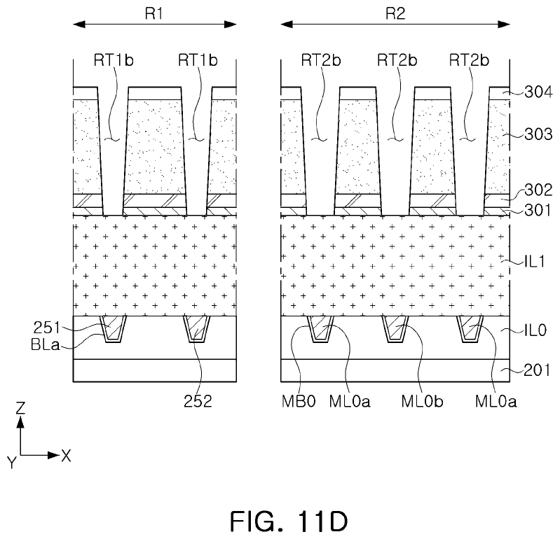

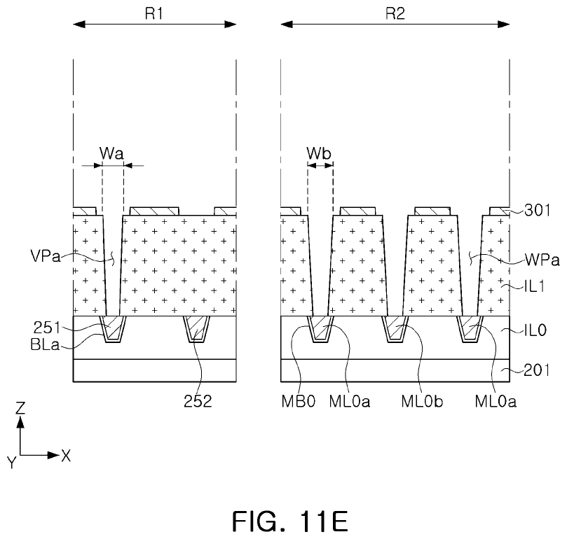

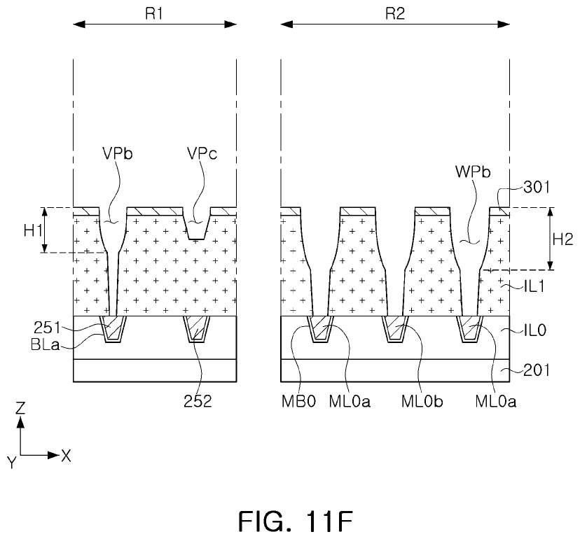

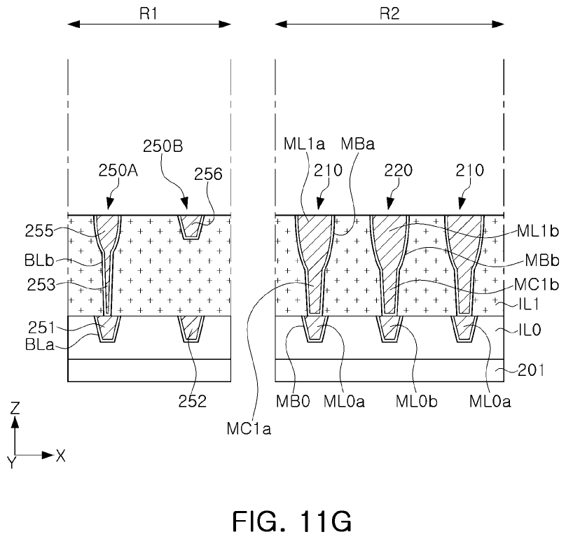

FIGS. 11A to 11G are diagrams describing a method of manufacturing a semiconductor device according to some example embodiments. With reference to FIGS. 11A to 11G, the process of manufacturing of the lower interconnection structure 250 and capacitor structure 200 of the peripheral circuit structure PERI in FIG. 10 will be described.

Referring to FIG. 11A, a first insulating layer IL0 on a substrate 201, first and second lower interconnections 251 and 252 on the first region R1, first and second lower electrodes ML0a and ML0b, on the second region R2, a second insulating layer IL1 on the first insulating layer IL0, a conductive liner 301 on the second insulating layer IL1, and a first interlayer insulating film 302 on the conductive liner 301 may be formed in order.

The first insulating layer IL0 may be formed on the substrate 201. The first and second lower interconnections 251 and 252 and the first and second lower electrodes ML0a and ML0b may be filled on an upper surface of the first insulating layer IL0.

The first and second lower interconnections 251 and 252 on the first region R1 and the first and second lower electrodes ML0a and ML0b on the second region R2 may be formed on the same level. The first and second lower interconnections 251 and 252 and the first and second lower electrodes ML0a and ML0b may be formed by a damascene process. A barrier conductive film BLa may be formed between the first and second lower interconnections 251 and 252 and the first insulating layer IL0. A barrier conductive film MB0 may be formed between the first and second lower electrodes ML0a and ML0b and the first insulating layer IL0.

The second insulating layer IL1, the conductive liner 301 and the first interlayer insulating film 302 may be sequentially formed on the first insulating layer IL0.

The conductive liner 301 may include a conductive material, for example, at least one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN) and combinations thereof, but some example embodiments thereof are not limited thereto.

The first interlayer insulating film 302 may include at least one of silicon nitride (SiN), silicon oxynitride (SiON), silicon carbonitride (SiCN) and combinations thereof, but some example embodiments thereof are not limited thereto.

Referring to FIG. 11B, a first trench RT1a exposing the second insulating layer IL1 in first region R1 and a second trench RT2a exposing the second insulating layer IL1 in second region R2 may be formed by etching the conductive liner 301 and the first interlayer insulating film 302.

The first trench RT1a may overlap the first and second lower interconnections 251 and 252 in the vertical direction (Z-direction). The second trench RT2a may overlap the first and second lower electrodes ML0a and MLb0 in the vertical direction (Z-direction).

Referring to FIG. 11C, a hard mask 303 and a second interlayer insulating film 304 may be formed in order on the first interlayer insulating film 302. The hard mask 303 may cover the first interlayer insulating film 302 and may fill the first trench RT1a and the second trench RT2a. The hard mask 303 may include a spin-on hardmask (SOH), but some example embodiments thereof are not limited thereto. A second interlayer insulating film 304 may be formed on the hard mask 303. In some example embodiments, the second interlayer insulating film 304 may include the same materials as that of the first interlayer insulating film 302, but some example embodiments thereof are not limited thereto, and may include at least one of silicon nitride (SiN), silicon oxynitride (SiON), silicon carbonitride (SiCN) and combinations thereof.

Referring to FIG. 11D, the second interlayer insulating film 304, the hard mask 303, the first interlayer insulating film 302, and the conductive liner 301 may be etched in order, thereby forming a first opening RT1b in the first region R1 and a second opening RT2b in the second region R2.

The first opening RT1b may penetrate the second interlayer insulating film 304, the hard mask 303, the first interlayer insulating film 302, and the conductive liner 301 and may expose a region of the second insulating layer IL1 overlapping the first and second lower interconnections 251 and 252.

The second opening RT2b may penetrate the second interlayer insulating film 304, the hard mask 303, the first interlayer insulating film 302, and the conductive liner 301 and may expose a region of the second insulating layer IL1 overlapping the first and second lower electrodes ML0a and MLb0.

Referring to FIG. 11E, a via hole VPa penetrating the second insulating layer IL1 and exposing the first lower interconnection 251, and a third opening WPa penetrating the second insulating layer IL1 and exposing the first and second lower electrodes ML0a and ML0b, may be formed by etching through the first and second openings RT1b and RT2b. The via hole VPa may have a cylindrical shape, and the third opening WPa may have a trench shape extending in the second direction (Y-direction) and exposing the first and second lower electrodes ML0a and MLb0. In some example embodiments, the width Wa in the first direction (X-direction) of the via hole VPa may be smaller than the width Wb in the first direction (X-direction) of the third opening WPa. Remaining portions of the second interlayer insulating film 304, the hard mask 303 and the first interlayer insulating film 302 may be removed after the etching.

Referring to FIG. 11F, the third trench VPb, the fourth trench VPc and the fifth trench WPb may be formed in the second insulating layer IL1 using the conductive liner 301 as an etching mask.

Since the third trench VPb overlaps the via hole VPa, the third trench VPb may be integrated with the via hole VPa. The third trench VPb may have a curved side surface formed on the via hole VPa and extending from the linear side surface of the via hole VPa. The third trench VPb may have a first height H1 from an upper surface of the conductive liner 301 to a lower surface of the curved side surface in the third direction (Z-direction).

The fourth trench VPc may be configured as a region overlapping the second lower interconnection 252 and may be connected to the second lower interconnection 252 through a via hole (or through-plug) in a region not illustrated. A depth of the fourth trench VPc in the vertical direction (Z-direction) may be smaller than a depth of the third trench VPb in the vertical direction (Z-direction).

Since the fifth trench WPb overlaps the third opening WPa, the fifth trench WPb may be integrated with the third opening WPa. The fifth trench WPb may have a curved side surface formed on the third opening WPa and extending from the linear side surface of the third opening WPa. The fifth trench WPb may have a second height H2 having the curved side surface in the third direction (Z-direction) from the upper surface of the conductive liner 301 to a lower surface of the curved side surface in the third direction (Z-direction). A second height H2 of the fifth trench WPb may be greater than the first height H1 of the third trench VPb. The fifth trench WPb may be formed by etching to a greater depth from the upper surface of the conductive liner 301 than the third trench VPb.

Referring to FIG. 11G, the first peripheral contact plug 253 and the first peripheral interconnection 255 may be formed in the third trench VPb, the second peripheral interconnection 256 may be formed in the fourth trench VPc, the second peripheral interconnection 256 may be formed in the fourth trench VPc, and the first wall patterns MC1a and MC1b and the second wall patterns ML1a and ML1b may be formed in the fifth trench WPb.

Before the first wall patterns MC1a and MC1b and the second wall patterns ML1a and ML1b are formed, barrier conductive films MBa and MBb may be formed conformally along a bottom surface and a side surface of the fifth trench WPb.

Before the first peripheral contact plug 253 and the first peripheral interconnection 255 are formed, a barrier conductive film BLb may be formed along a bottom surface and a side surface of the third trench VPb. Before the second peripheral interconnection 256 are formed, a conductive film may be formed along a bottom surface and a side surface of the fourth trench VPc.

The method of manufacturing a semiconductor device according to some example embodiments may include forming the first electrode structure 210 and the second electrode structure 220 of the capacitor structure 200 in the same process as a process of forming the lower interconnection structure 250, and forming the first wall patterns MC1a and MC1b and the second wall patterns ML1a and ML1b included in the first electrode structure 210 and the second electrode structure 220, along with the peripheral contact plug 253 and the peripheral interconnection 255 through a dual damascene process. Accordingly, by reducing a spacing distance between the capacitor structure 200 and the lower interconnection structure 250, a semiconductor device having improved integration density may be provided.

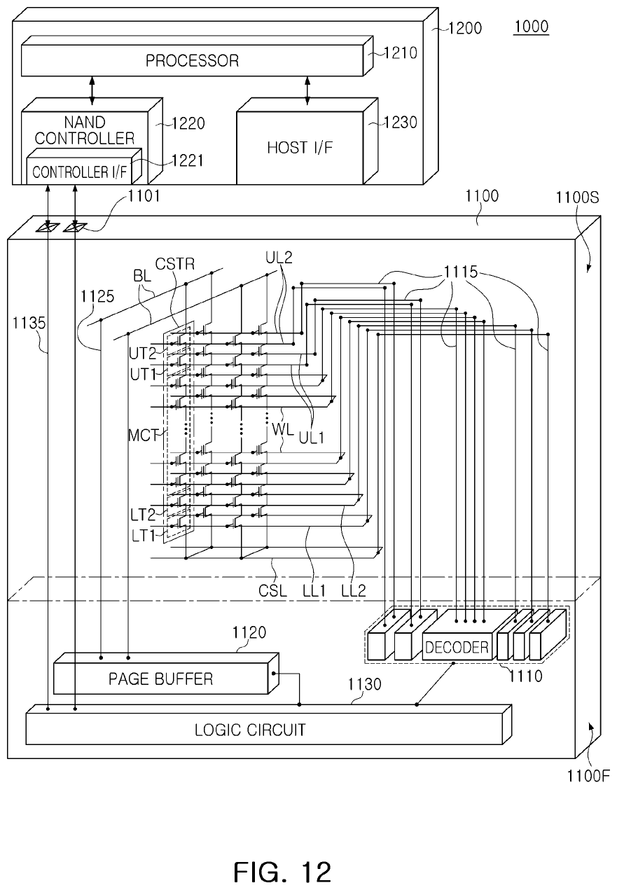

FIG. 12 is a diagram illustrating a data storage system including a semiconductor device according to some example embodiments.

Referring to FIG. 12, a data storage system 1000 may include a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 6B. The semiconductor device 1100 may include a first structure 1100F and a second structure 1100S on the first structure 1100F. In some example embodiments, the first structure 1100F may be disposed on the side of the second structure 1100S. The first structure 1100F may be implemented as a peripheral circuit structure including a decoder circuit 1110, a page buffer 1120, and a logic circuit 1130. For example, the first structure 1100F may include pumping capacitors CAP1 and an output capacitor CAP2 of the charge pump circuit 56b included in the voltage generator 38 (e.g., see FIGS. 1A-1C). The second structure 1100S may be implemented as a memory cell structure including a bit line BL, a common source line CSL, word lines WL, first and second gate upper lines UL1 and UL2, first and second gate lower lines LL1 and LL2 and memory cell strings CSTR disposed between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in some example embodiments.

In some example embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The word lines WL may be configured as gate electrodes of the memory cell transistors MCT, and the gate upper lines UL1 and UL2 may be configured as gate electrodes of the upper transistors UT1 and UT2, respectively.

In some example embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S. The bit lines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 may include a processor 1210, a NAND controller 1220, and a host interface 1230. In some example embodiments, the data storage system 1000 may include a plurality of semiconductor devices 1100, and in some example embodiments, the controller 1200 may control the plurality of semiconductor devices 1100.

The processor 1210 may control overall operation of the data storage system 1000 including the controller 1200. The processor 1210 may operate according to predetermined firmware, and may access the semiconductor device 1100 by controlling the NAND controller 1220. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

According to the aforementioned example embodiments, the semiconductor device and the data storage system including the same may include a capacitor structure and a lower interconnection structure disposed on the same level as a level of the capacitor structure. The first electrodes and second electrodes of the capacitor structure may include a first wall pattern having a first side surface and a second wall pattern extending from the first side surface, respectively, and the lower interconnection structure may include a peripheral contact plug and a peripheral interconnection having a line shape extending from the peripheral contact plug. Accordingly, line width roughness (LWR) of the first electrodes and the second electrodes of the capacitor structure may be improved, and the interconnection alignment of the peripheral interconnection of the lower interconnection structure may be improved, such that a semiconductor device having improved reliability and a data storage system including the same may be provided.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While some example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure including a substrate, circuit devices on the substrate, a lower interconnection structure electrically connected to the circuit devices, and a capacitor structure spaced apart from the lower interconnection structure; and
a second semiconductor structure including a plate layer on the first semiconductor structure, the second semiconductor structure including gate electrodes spaced apart from each other and stacked in order on the plate layer in a vertical direction perpendicular to an upper surface of the plate layer, and channel structures penetrating the gate electrodes and extending in the vertical direction,
wherein the capacitor structure includes
a first electrode structure including first electrodes spaced apart from each other in a first direction parallel to an upper surface of the substrate, the first electrodes extending in the vertical direction and extending in a second direction intersecting the first direction, and
a second electrode structure including second electrodes arranged alternately with the first electrodes along the first direction, the second electrodes extending in the second direction,
wherein the first electrodes and the second electrodes each include a first wall pattern having a first side surface and a second wall pattern having a second side surface, the second side surface extending from the first side surface, and
wherein a side surface profile of the first and second electrodes changes nonlinearly at a boundary between the first side surface and the second side surface.

2. The semiconductor device of claim 1,
wherein the first side surface has a linear shape, and a width of the first wall pattern in the first direction increases along an upwardly increasing height of the first wall pattern in the vertical direction, and
wherein the second side surface extends from the first side surface and has a curved shape.

3. The semiconductor device of claim 1, wherein the capacitor structure further includes a barrier conductive film covering a bottom surface of the first wall pattern, the first side surface of the first wall pattern and the second side surface of the second wall pattern.

4. The semiconductor device of claim 1,
wherein the first electrode structure further includes a first connection portion connecting the first electrodes to each other, the first connection portion extends in the first direction, and
wherein the second electrode structure is spaced apart from the first connection portion in the second direction, the second electrode structure further includes a second connection portion connecting the second electrodes to each other, and the second connection portion extends in the first direction.

5. The semiconductor device of claim 4, wherein an upper surface of the first connection portion and an upper surface of the second connection portion are at a same level as a level of an upper surface of the second wall pattern.

6. The semiconductor device of claim 4, wherein a lower surface of the first connection portion and a lower surface of the second connection portion are at a level higher than a level of a lower surface of the first wall pattern.

7. The semiconductor device of claim 4, wherein the capacitor structure further includes:
a first lower electrode structure between the substrate and the first electrode structure, the first lower electrode structure including first lower electrodes overlapping the first electrodes and a first lower connection portion connecting the first lower electrodes to each other, and the first lower connection portion extending in the first direction; and
a second lower electrode structure between the substrate and the second electrode structure, the second lower electrode structure including second lower electrodes overlapping the second electrodes and a second lower connection portion connecting the second lower electrodes to each other, the second lower connection portion extending in the first direction,
wherein the first lower connection portion overlaps the second connection portion, and
wherein the second lower connection portion overlaps the first connection portion.

8. The semiconductor device of claim 4, wherein the capacitor structure further includes:
a first upper electrode structure on the first electrode structure, the first upper electrode structure including first upper electrodes overlapping the first electrodes and a first upper connection portion connecting the first upper electrodes to each other, the first upper connection portion extending in the first direction; and
a second upper electrode structure on the second electrode structure, the second upper electrode structure including second upper electrodes overlapping the second electrodes and a second upper connection portion connecting the second upper electrodes to each other, the second upper connection portion extending in the first direction,
wherein the first upper connection portion overlaps the second connection portion, and
wherein the second upper connection portion overlaps the first connection portion.

9. The semiconductor device of claim 8, wherein a height of the first upper electrode structure in the vertical direction is greater than a height of the first electrode structure in the vertical direction.

10. The semiconductor device of claim 8,
wherein the first upper electrodes and the second upper electrodes each include a third wall pattern having a third side surface and a fourth wall pattern having a fourth side surface, the fourth wall pattern extending from the third wall pattern, and
wherein a side surface profile changes nonlinearly at a boundary between the third side surface and the fourth side surface.

11. The semiconductor device of claim 1,
wherein the lower interconnection structure is spaced apart from the capacitor structure in the first direction, and
wherein the lower interconnection structure is at a same level as a level of the first wall pattern, the lower interconnection structure including a contact plug having a cylindrical shape and a peripheral interconnection on the contact plug and in contact with an upper surface of the contact plug, the peripheral interconnection extending in the second direction.

12. The semiconductor device of claim 11,
wherein an upper surface of the peripheral interconnection is at a same level as a level of an upper surface of the second wall pattern, and
wherein a height of the peripheral interconnection in the vertical direction is less than a height of the second wall pattern in the vertical direction.

13. The semiconductor device of claim 11, wherein the lower interconnection structure further includes a peripheral barrier film covering a lower surface of the contact plug, a side surface of the contact plug, and a side surface of the peripheral interconnection.

14. The semiconductor device of claim 11, wherein a width of the peripheral interconnection in the first direction is smaller than a width of the second wall pattern in the first direction.

15. A semiconductor device, comprising:
a first lower electrode structure on a substrate, the first electrode structure including first lower electrodes and a first lower connection portion, the first lower electrodes being spaced apart from each other in a first direction parallel to an upper surface of the substrate and extending in a second direction intersecting the first direction, and the first lower connection portion connecting the first lower electrodes to each other and extending in the first direction;
a second lower electrode structure including second lower electrodes and a second lower connection portion, the second lower electrodes being arranged alternately with the first lower electrodes along the first direction, and the second lower connection portion connecting the second lower electrodes to each other and extending in the first direction;
a first insulating layer between the first lower electrode structure and the second lower electrode structure;
a first intermediate electrode structure including first intermediate electrodes and a first intermediate connection portion, the first intermediate electrodes being on the first lower electrodes, and the first intermediate connection portion connecting the first intermediate electrodes to each other and extending in the first direction, the first intermediate connection portion overlapping the second lower connection portion in a vertical direction;
a second intermediate electrode structure including second intermediate electrodes and a second intermediate connection portion, the second intermediate electrodes being on the second lower electrodes, and the second intermediate connection portion connecting the second intermediate electrodes to each other and extending in the first direction, and the second intermediate connection portion overlapping the first lower connection portion in the vertical direction; and
a second insulating layer between the first intermediate electrode structure and the second intermediate electrode structure,
wherein the first intermediate electrodes and the second intermediate electrodes each include a first wall pattern having a first side surface and a second wall pattern having a second side surface, the second side surface extending from the first side surface, and
wherein a side surface profile of the first and second intermediate electrodes changes nonlinearly at a boundary between the first side surface and the second side surface.

16. The semiconductor device of claim 15,
wherein the first wall pattern includes a 1-1 wall pattern on the first lower electrodes and a 1-2 wall pattern on the second lower electrodes, and
wherein the second wall pattern includes a 2-1 wall pattern extending from the 1-1 wall pattern and a 2-2 wall pattern extending from the 1-2 wall pattern.

17. The semiconductor device of claim 15,
wherein a lower surface of the first lower connection portion is at a same level as a level of a lower surface of the first lower electrodes, and
wherein a lower surface of the first intermediate connection portion is at a level higher than a level of a lower surface of the first intermediate electrodes.

18. The semiconductor device of claim 15, further comprising:
a first upper electrode structure including first upper electrodes and a first upper connection portion, the first upper electrodes being on the first intermediate electrodes, and the first upper connection portion connecting the first upper electrodes to each other and extending in the first direction, the first upper connection portion overlapping the second intermediate connection portion in the vertical direction;
a second upper electrode structure including second upper electrodes and a second upper connection portion, the second upper electrodes being on the second intermediate electrodes, and the second upper connection portion connecting the second upper electrodes to each other and extending in the first direction, the second upper connection portion overlapping the first intermediate connection portion in the vertical direction; and
a third insulating layer between the first upper electrode structure and the second upper electrode structure.

19. A data storage system, comprising:
a semiconductor storage device including circuit devices, memory cells, capacitor structures, and input/output pads on a substrate; and
a controller configured to control the semiconductor storage device, the controller being electrically connected to the semiconductor storage device through the input/output pads,
wherein the capacitor structure includes
a first electrode structure including first electrodes and a first connection portion, the first electrodes being spaced apart from each other in a first direction parallel to an upper surface of the substrate and extending in a second direction intersecting the first direction, and the first connection portion connecting the first electrodes to each other and extending in the first direction,
a second electrode structure including second electrodes and a second connection portion, the second electrodes being arranged alternately with the first electrodes along the first direction and extending in the second direction, and the second connection portion connecting the second electrodes to each other and extending in the first direction, and
an insulating layer between the first electrode structure and the second electrode structure,
wherein the first electrodes and the second electrodes each include a first wall pattern having a first side surface and a second wall pattern having a second side surface, the second side surface extending from the first side surface, and
wherein a lower surface of the first connection portion and a lower surface of the second connection portion are at a level higher than a level of a lower surface of the first wall pattern.

20. The data storage system of claim 19, wherein the first connection portion and the second connection portion are spaced apart from each other in the second direction.
